(19) United States
(12) Patent Application Publication
(10) Pub. No.: US 2024/0118336 A1
(43) Pub. Date: Apr. 11, 2024

(54) CUSTOMIZABLE SAFETY ENCLOSURE FOR A DEVICE UNDER TEST

(71) Applicant: Tektronix, Inc., Beaverton, OR (US)

(72) Inventor: David Thomas Engquist, Portland, OR (US)

(73) Assignee: Tektronix, Inc., Beaverton, OR (US)

(21) Appl. No.: 18/485,257

(22) Filed: Oct. 11, 2023

Related U.S. Application Data
(60) Provisional application No. 63/415,217, filed on Oct. 11, 2022.
(60) Provisional application No. 63/415,219, filed on Oct. 11, 2022.
(60) Provisional application No. 63/415,221, filed on Oct. 11, 2022.
(60) Provisional application No. 63/452,811, filed on Mar. 17, 2023.

(51) Int. Cl. G01R 31/28

(52) U.S. Cl. CPC G01R 31/2808

(57) ABSTRACT

A customizable safety enclosure for a device under test (DUT) includes a plurality of non-conductive panels to enclose the DUT, and a plurality of non-conductive removeable corner joints each configured to secure a corner of the enclosure. A method of supplying a customized safety enclosure for a DUT to a customer includes receiving information from the customer about the DUT size and testing environment, fabricating one or more variable components of the enclosure, producing custom assembly instructions for the enclosure, packaging a plurality of components of the enclosure including the variable components and one or more fixed components, and sending the package of components and the custom assembly instructions to the customer.

### CROSS-REFERENCE TO RELATED APPLICATIONS

This application claims the benefit of U.S. Prov. Pat. App. No. 63/415,217, filed Oct. 11, 2022, U.S. Prov. Pat. App. No. 63/415,219, filed Oct. 11, 2022, U.S. Prov. Pat. App. No. 63/415,221, filed Oct. 11, 2022, and U.S. Prov. Pat. App. No. 63/452,811, filed Mar. 17, 2023. Each of these prior-filed applications is hereby incorporated by reference in its entirety into this application.

### TECHNICAL FIELD

This disclosure relates to test and measurement systems including a test and measurement instrument and/or probe connected to a device under test (DUT), and more particularly relates to a safety enclosure for the DUT.

### BACKGROUND

Probe users often employ safety enclosures to isolate and provide barriers and distance between their hazardous voltage Devices Under Test (DUTs) and users to prevent shocks and kinetic events from exploding components. Such safety enclosures help ensure and maintain safe spacing and a barrier between an energized circuit and the probe user.

However, most safety enclosure applications either use metallic panels or molded-in features for injection molded enclosure covers or chassis. Safety enclosures that use metal components on the surface of the enclosure tend to breach exterior to interior, allowing hazardous current to egress if an internal hazardous voltage conductor contacted or came within air discharge vicinity to that component while a user simultaneously contacted or came within air discharge vicinity. The conductive nature of metal components presents an arcing and subsequent shock risk if they happen to be in contact with or within creepage/clearance range of a hazardous DUT and an unprotected user.

Most safety enclosures seen at customer sites tend to be independently developed and fabricated by the end-user, requiring users to come up with drawing specifications, gather necessary material and tools, including fasteners, and engage a fabricator to assemble and deploy a safety enclosure solution.

### BRIEF DESCRIPTION OF THE DRAWINGS

FIG. 1 shows an example of a customizable safety enclosure for a device under test (DUT), according to embodiments of the disclosure.

FIG. 2 shows examples of features of a customizable safety enclosure for a device under test (DUT), according to embodiments of the disclosure.

FIG. 3 shows an example of a corner joint, according to embodiments of the disclosure.

FIG. 4 shows an example of engagement between a corner joint and a panel, according to embodiments of the disclosure.

FIG. 5 shows examples of features of a corner joint, according to embodiments of the disclosure.

FIG. 6 shows examples of features of a corner joint, according to embodiments of the disclosure.

FIGS. 7A, 7B, and 7C shows an example of a corner joint and its three possible orientations of symmetry, according to embodiments of the disclosure.

FIG. 8 shows an example of an edge joint, according to embodiments of the disclosure.

FIG. 9 shows an example of engagement between an edge joint and a panel, according to embodiments of the disclosure.

FIG. 10 shows examples of features of an edge joint, according to embodiments of the disclosure.

FIGS. 11A and 11B show an example of an edge joint and its two possible orientations of symmetry, according to embodiments of the disclosure.

FIG. 12 shows an example of a hinge and an access door, according to embodiments of the disclosure.

FIG. 13 shows an example of a hinge and an access door, according to embodiments of the disclosure.

FIG. 14 shows an example of a hinge and an access door, according to embodiments of the disclosure.

FIG. 15 shows an example of a DUT support post and a DUT, according to embodiments of the disclosure.

FIG. 16 shows an example of a DUT support post, according to embodiments of the disclosure.

FIG. 17 shows an example of process for installing a DUT support post, according to embodiments of the disclosure.

FIG. 18 shows an example of a PCB holder, according to embodiments of the disclosure.

FIG. 19 shows a cross-section of an example of a PCB holder, according to embodiments of the disclosure.

FIG. 20 shows examples of safety enclosures in a variety of form factors, according to embodiments of the disclosure.

FIG. 21 shows an example of a method of providing a customized safety enclosure to a customer, according to embodiments of the disclosure.

FIG. 22 shows an example of a packaging method for a customized safety enclosure, according to embodiments of the disclosure.

### DETAILED DESCRIPTION

Disclosed herein is a customizable safety enclosure for a Device Under Test (DUT). The enclosure helps maintain safe spacing and a barrier between an energized circuit and a user, protecting a user who operates a high-voltage DUT from electrical shock hazards while testing the DUT using, for example, a test probe and a test and measurement instrument such as an oscilloscope. It also provides some protection against kinetic activity from exploding DUT components that may occur if the DUT fails due to excessive voltage/current loads. Size and features of a customizable safety enclosure may vary depending on customer requirements and DUT configuration according to different embodiments of the disclosure.

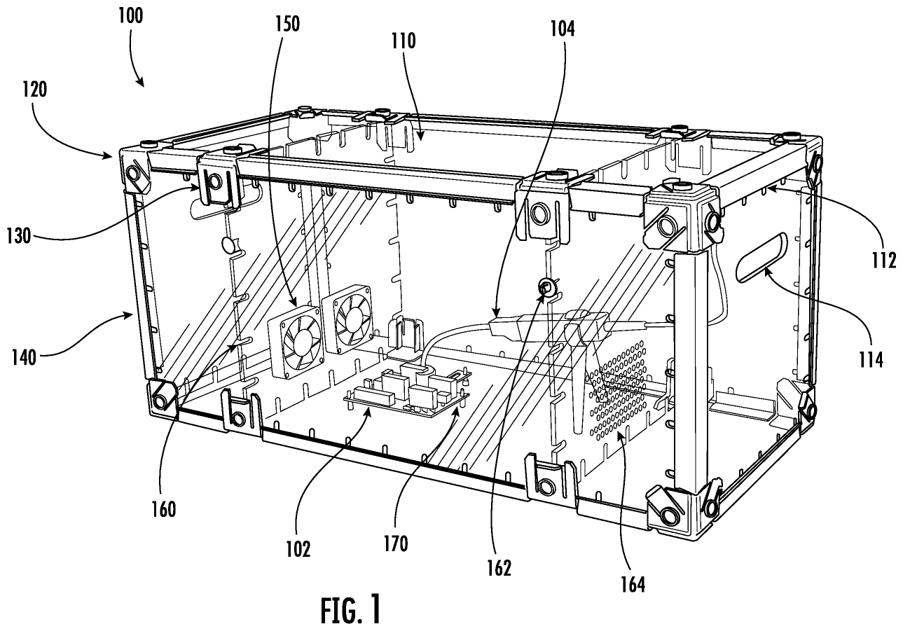

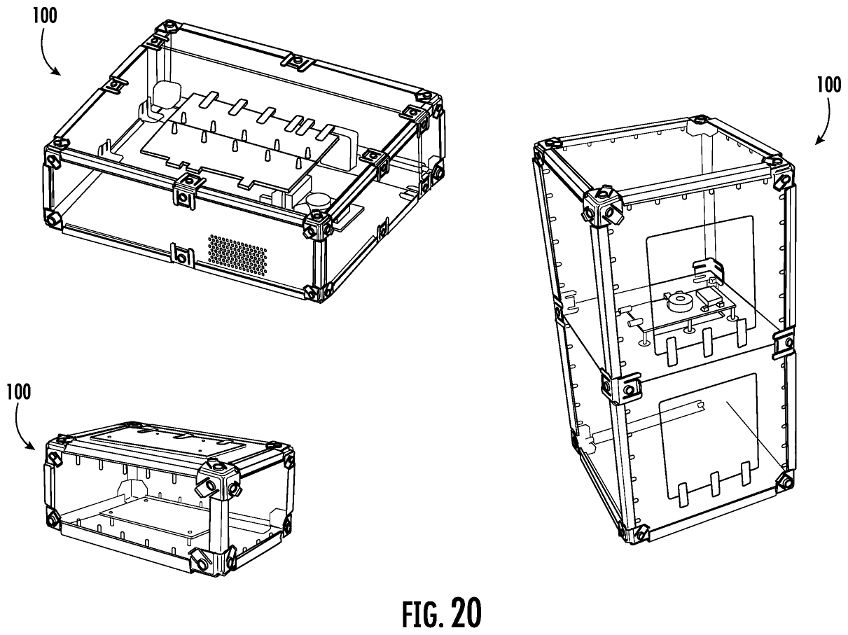

FIG. 1 illustrates an example customizable safety enclosure 100, according to some embodiments of the disclosure, for protecting a customer who operates a high-voltage DUT. Users can create a customized design for their safety enclosure by configuring and modeling it with their DUT size and mounting profile. Example possible configurations for the customized design include configurations that are flat, tall, and small, such as the example safety enclosures 100 shown in FIG. 20. Additional factors considered include probes configuration, safety spacings, and environmental constraints such as bench space size and overhead constraints like shelving.

The customizable safety enclosure 100 includes multiple panels 110 to enclose the DUT 102. The panels 110 are electrically non-conductive to reduce the risk of electric shock to a user outside the enclosure 100. The panels 110 are typically made of a transparent material so a user can visually observe the DUT and/or any testing equipment 104 inside the enclosure 100. However, embodiments of the disclosure are not necessarily limited to transparent panels. The panels 110 are typically made of a plastic material such as Lexan, for example. The panels 110 are generally sized and shaped to a customer's DUT configuration, and mate with other sub-parts and sub-assemblies to help join and customize the enclosure 100, as discussed in more detail below. The panels 110 generally define the overall size and shape of the enclosure 100, and may, according to some embodiments, be produced in completely custom sizes, or may, according to other embodiments, be produced in a fixed number of predetermined sizes. The panels 110 provide a fully enclosed electrically insulative barrier between the DUT and the outside environment. According to some embodiments, in which the enclosure 100 is generally a cuboid shape, the enclosure 100 typically includes six panels 110: a top panel, a bottom panel, a left side panel, a right side panel, a front panel and a back panel.

The customizable safety enclosure 100 may also include one or more cable egress openings 112. The cable egress opening 112 is structured to allow, for example, a probe cable that conveys signals from a test probe connected to the DUT inside the enclosure to a test and measurement instrument outside the enclosure. In some embodiments, the cable egress opening 112 may comprise one or more cable egress slots formed in one or more of the panels 110, as shown in FIG. 1. The cable egress slots may be standard slots in a regular pattern spaced adjacent to edge guards 140, discussed further below, intended to allow cables for probes, DMM leads, power, signal, or logic to pass through the enclosure and interface with DUT. A single cable egress opening 112 is large enough for a cable to pass but small enough to create a barrier for a human digit to pass. This helps in providing limited egress opportunities for current to escape the customizable safety enclosure by limiting aperture sizes to smaller than adult human digits and metal conductive paths from the interior to the exterior.

According to some embodiments, one or more of the panels 110 may also include a handle 114, to allow easy transport of the enclosure 100. In some embodiments, handle 114 may simply be a hole in a panel 110, as shown in FIG. 1, although this type of handle 114 should be used in conjunction with one or more divider panels, as discussed below. In other embodiments, a fully insulated impermeable plastic handle insert with finger indentation could be inserted into this hole which could provide the same protection as the afore mentioned divider panel.

As shown in FIG. 1, embodiments of a customizable safety enclosure may include two types of non-conductive joints: corner joints 120 and edge joints 130. The customizable safety enclosure 100 includes a plurality of non-conductive removeable corner joints 120. The corner joints 120 engage the corners of the panels 110 to secure the corners of the customizable safety enclosure 100. In some common embodiments, in which the enclosure is a typical cuboid shape as illustrated in FIG. 1, there are eight corner joints 120—four top corner joints and four bottom corner joints—each corner joint engaging with the corners of three orthogonal panels 110. However, according to other embodiments, the enclosure 100 may have a more complicated shape, which uses a different number of corner joints 120.

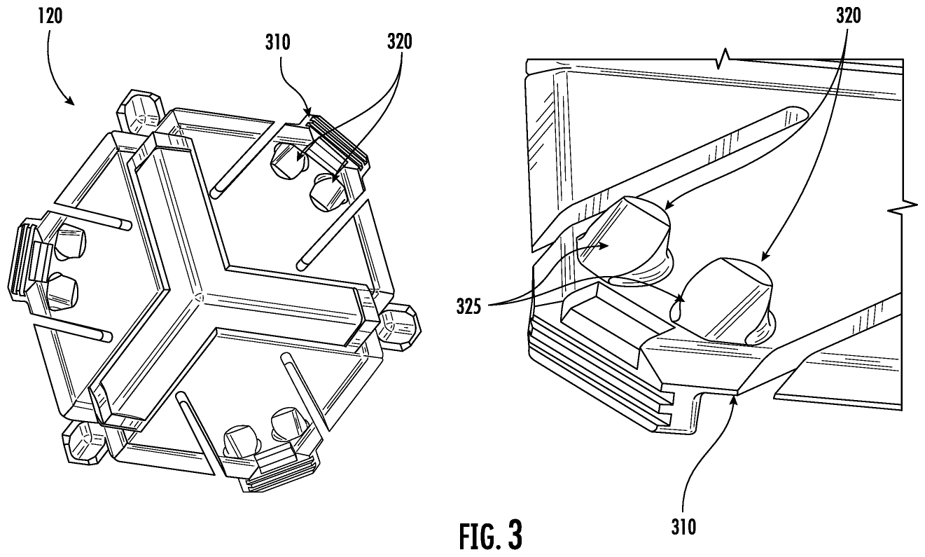

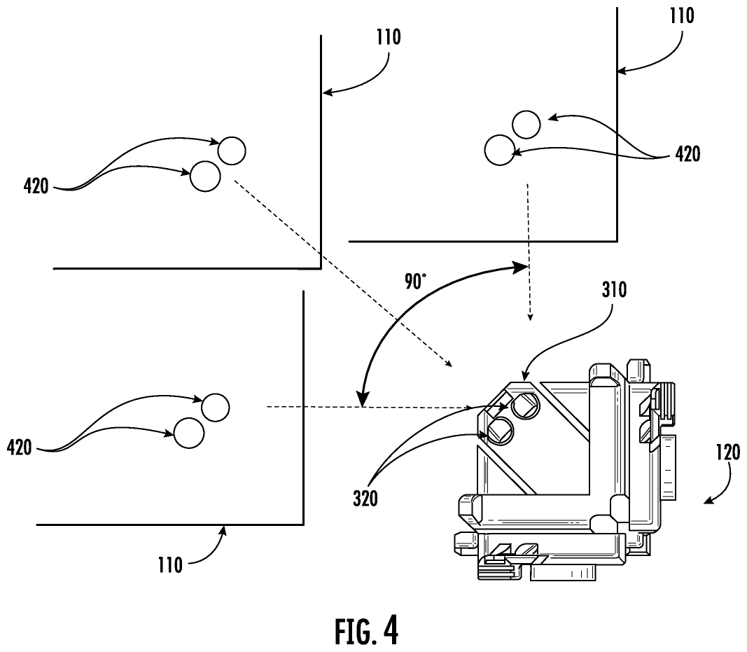

The corner joints 120 are structured to be removeable and installable, by a user, without using tools or fasteners. Not requiring fasteners promotes user efficiency because the use of fasteners tends to be more time-consuming for users to assemble and disassemble. Instead of fasteners, as shown in FIG. 3, the corner joints include retention bosses 320 on a cantilever tab/snap 310. The retention bosses 320 engage a corresponding hole pattern 420 milled into each panel 110 corner, as illustrated by FIG. 4. As shown in FIG. 3, the retention bosses 320 have various oblique surfaces, e.g. lead-in ramps 325, that act as assembly lead-in from a variety of panel engagement directions. The lead-in surfaces 325 provide easier engagement of the corner joints 120 with the panels, and positive confirmation of installation to a user as the retention bosses 320 snap fit into place, without requiring any tools for installation.

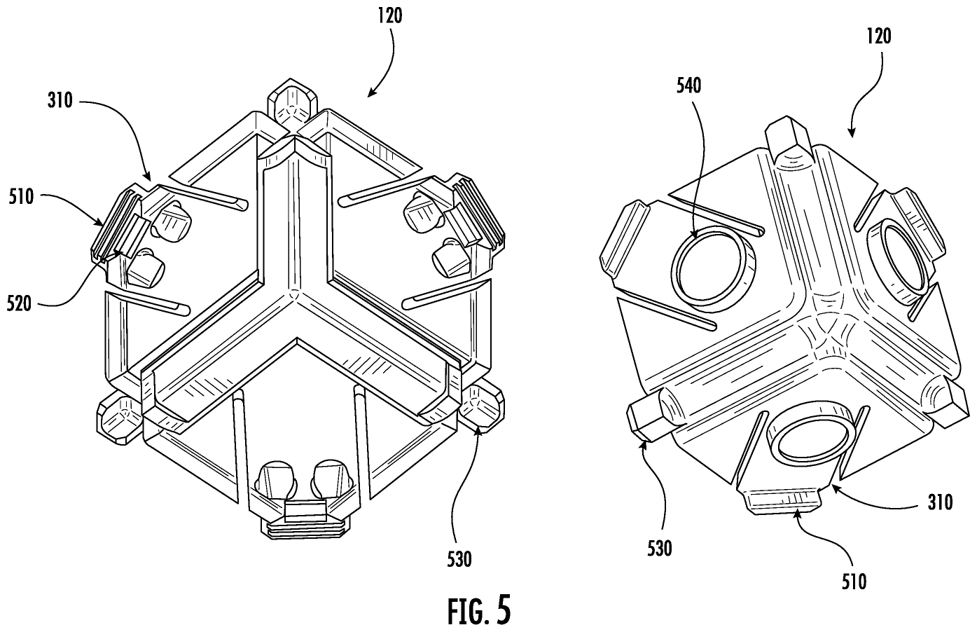

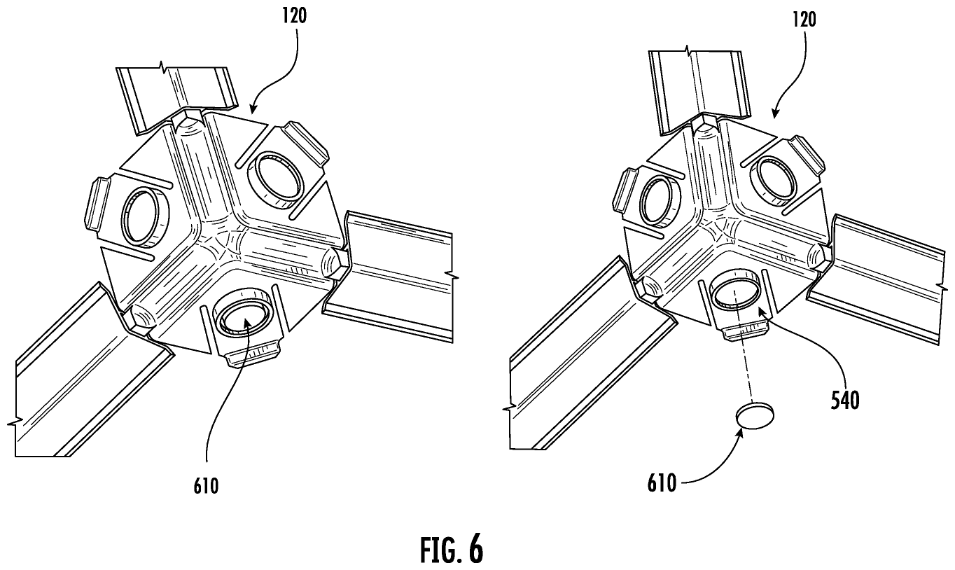

FIG. 5 shows perspective views of the inner surfaces and the outer surfaces of the corner joints 120, to illustrate additional features of the corner joints 120, according to some embodiments. As shown in FIG. 5, the corner joints 120 may include thumb/finger grips 510. The finger grips 510 allow for easy disassembly and removal of the corner joint by lifting the cantilever tab 310 to remove retention bosses 320 from the panel hole pattern 420. Thus, the corner joints 120 are easily removable by a user without using tools. However, in some embodiments, a flat bladed screwdriver slot 520 may provide a pry point as an alternative method for disassembly. Bosses 530 may provide a support and retaining mechanism for an edge guard 140, discussed further below. Bosses 540 may provide a location for branding the assembly. As illustrated in FIG. 6, bosses 540 may also provide a location to add an anti-skid pad 610, which may act as a non-slip foot for the enclosure 100, particularly if these bosses 540 are bottom-facing when the enclosure 100 is assembled. These feet help to prevent the assembled enclosure 100 from sliding around on a work surface.

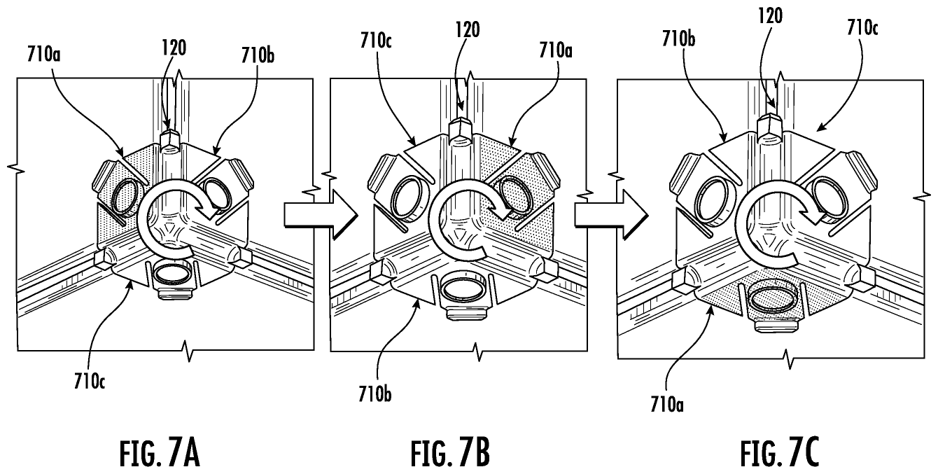

Installation of the corner joints 120 when assembling the enclosure 100 is made even easier for the user by having the corner joints structured to be installable symmetrically in three possible orientations. FIGS. 7A, 7B, and 7C illustrate that corner joints 120 possess a symmetry in three possible orientations such that if the part was rotated, it would appear the same with respect to adjoining panels and would therefore perform identically. That is, each of sections 710a, 710b, and 710c of corner joint 120 appears identical to the user and to the mating panels 110, no matter which of the three orientations shown in FIGS. 7A, 7B, and 7C the corner joint is positioned. By having three possible orientations, the user does not have to be concerned about which orientation is the correct one when assembling the customizable safety enclosure. Additionally, each orientation works identically, which reduces assembly time as well as chance of error.

As mentioned above, and as shown in FIG. 1, according to some embodiments, the customizable safety enclosure 100 may also include one or more non-conductive removable edge joints 130 that are configured to secure an edge of the enclosure 100. Edge joints 130 may provide additional mechanical strength and support for enclosures with shapes that have long edges, such as the cuboid shaped enclosure depicted in FIG. 1. The edge joints 130 engage two right angle panels 110 at one or more locations along the edge of the customizable safety enclosure 100 and are intended to locally fasten the edges together and reinforce the enclosure structure.

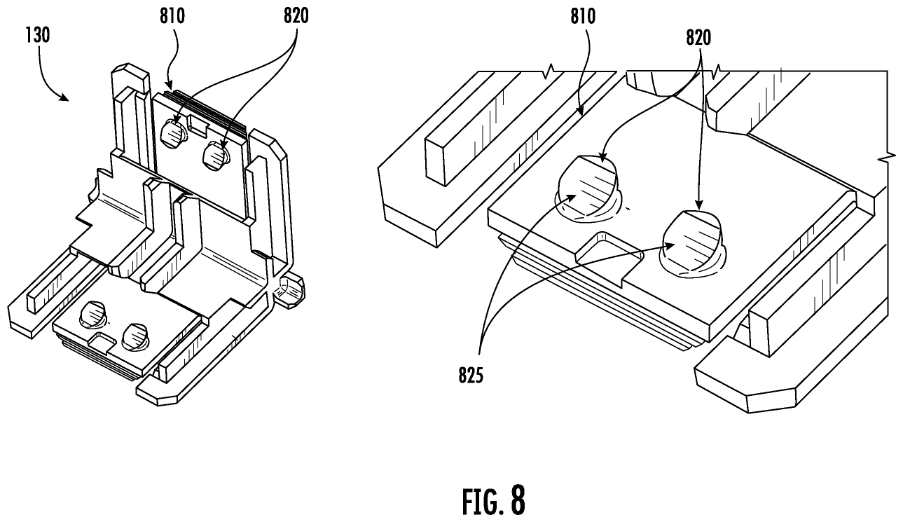

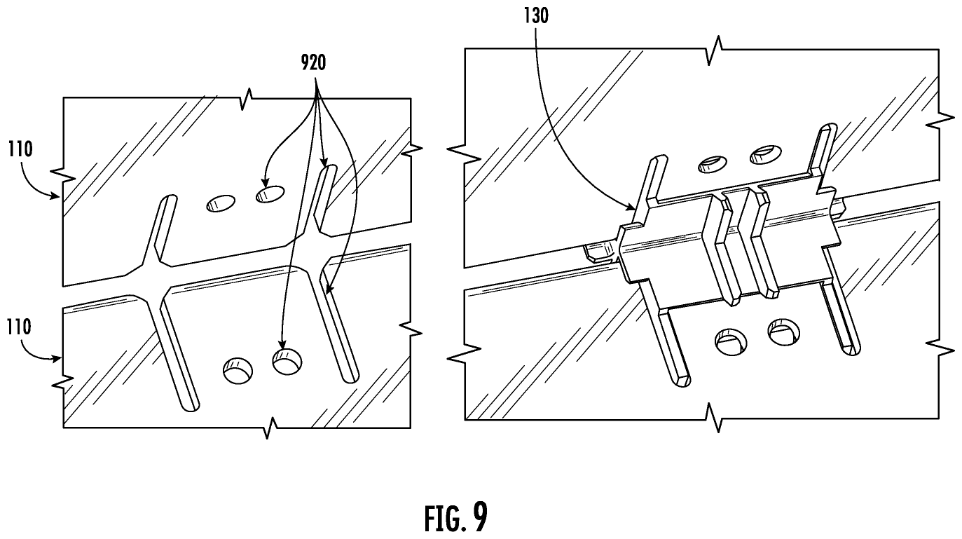

Similar to the corner joints 120, edge joints 130 are structured to be removable and installable, by a user, without using tools or fasteners. Not requiring fasteners promotes user efficiency because the use of fasteners tends to be more time-consuming for users to assemble and disassemble. Instead of fasteners, as shown in FIG. 8, the edge joints include retention bosses 820 on a cantilever tab/snap 810, similar to the corner joints 120. The retention bosses 820 engage a corresponding hole and slot pattern 920 milled into panel 110 edges, as illustrated by FIG. 9. As shown in FIG. 8, the retention bosses 820 have various oblique surfaces, e.g. lead-in ramps 825, that act as assembly lead-in from a variety of panel engagement directions. The lead-in surfaces 825 provide easier engagement of the edge joints 130 with the panels 110, and positive confirmation of installation to a user as the retention bosses 820 snap fit into place, without requiring any tools for installation.

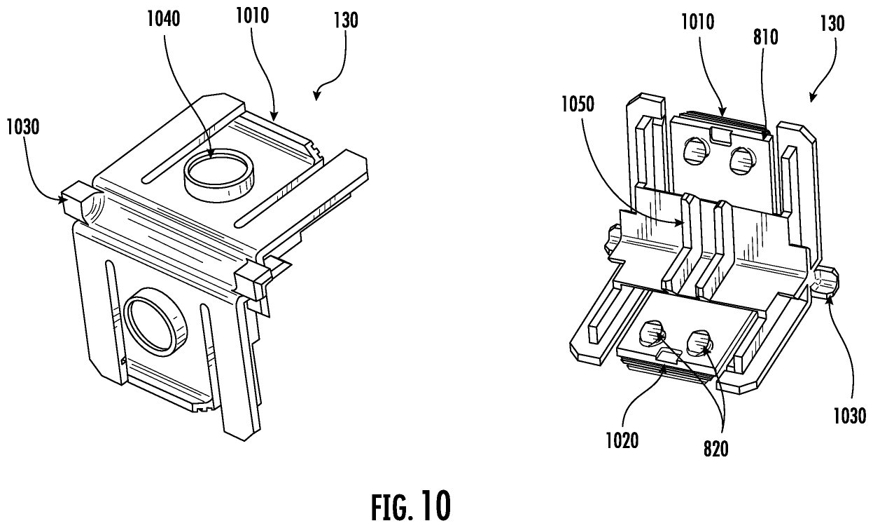

FIG. 10 shows perspective views of the inner surfaces and the outer surfaces of the edge joints 130, to illustrate additional features of the corner joints 130, according to some embodiments. As shown in FIG. 10, the edge joints 130 may include thumb/finger grips 1010. The finger grips 1010 allow for easy disassembly and removal of the edge joint by lifting the cantilever tab 810 to remove retention bosses 820 from the panel hole pattern 920. Thus, the edge joints 130 are easily removable by a user without using tools. However, in some embodiments, a flat bladed screwdriver slot 1020 may provide a pry point as an alternative method for disassembly. Bosses 1030 may provide a support and retaining mechanism for an edge guard 140, discussed further below. Bosses 1040 may provide a location for branding the assembly. Bosses 1040 may also provide a location to add an anti-skid pad, such as anti-skid pad 610, which may act as a non-slip foot for the enclosure 100, particularly if these bosses 540 are bottom-facing when the enclosure 100 is assembled. These feet help to prevent the assembled enclosure 100 from sliding around on a work surface. Additionally, in some embodiments, an edge joint 130 may also include walls 1050 to support and retain a divider 160, discussed further below.

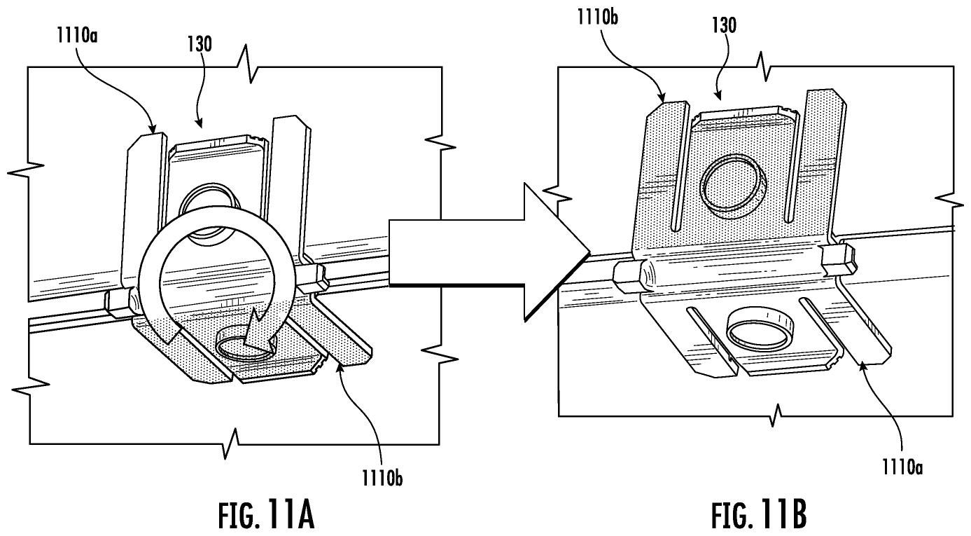

Installation of the edge joints 130 when assembling the enclosure 100 is made even easier for the user by having the edge joints structured to be installable symmetrically in two possible orientations. FIGS. 11A and 11B illustrate that edge joints 130 possess a symmetry in two possible orientations such that if the part was rotated, it would appear the same with respect to adjoining panels and would therefore perform identically. That is, both of sections 1110a and 1110b of edge joint 130 appears identical to the user and to the mating panels 110, no matter which of the two orientations shown in FIGS. 11A and 11B the edge joint is positioned. By having two possible orientations, the user does not have to be concerned about which orientation is the correct one when assembling the customizable safety enclosure. Additionally, each orientation works identically, which reduces assembly time as well as chance of error.

Both non-conductive corner joints 120 and edge joints 130 contribute to a user-friendly experience and versatility. For example, since the end-customer is the person intended to assemble the customizable safety enclosure, a positive customer experience can be offered with an easy assembly that is fast and provides little chance for error. The non-conductivity of the corner joints and edge joints helps in preventing exposure to electrical arcing through the customizable safety enclosure due to the lack of conductive surfaces along the outer surface of the customizable safety enclosure provided by the non-conductive corner joints and edge joints. The design of the non-conductive corner joints and edge joints provides configuration flexibility since both joints are easily suitable to many enclosure shapes and size configurations.

Both the corner joints 120 and the edge joints 130 may be made of a non-conductive material, such as plastic, for example. The corner joints 120 and the edge joints 130 may be manufactured using an additive manufacturing process, e.g. 3D printing. Alternatively, according to some embodiments, the corner joints 120 and edge joints 130 may be broken down into subcomponents, such as a spine portion, and identical wall portions, which may having tooling made to produce injection-molded subcomponents, and can then be joined together using various techniques such as ultrasonic welding or epoxy. A toolable corner joint 120 design would consist of a spine and three identical wall portions, and a toolable edge joint 130 design would consist of a spine and two identical wall portions.

Returning to FIG. 1, the enclosure 100 may also include one or more non-conductive edge guards 140. Edge guards 140 of the customizable safety enclosure 100 support panel 110 edges mechanically and provide an additional electric barrier at seams. The cross-section of the edge guard is of a fixed design, but the length can vary in tandem with panel size to ensure the seam is fully covered. As shown in FIGS. 5 and 10, the ends of each edge guard 140 may engage with a boss 530 on a corner joint 120 or boss 1030 on an edge joint 130, which secure the edge guard 140 in place and help to reinforce the assembled enclosure 100.

In some embodiments, cable egress openings 112 in the enclosure 100 may also provide passive ventilation for the enclosure 100. In some embodiments, the enclosure 100 may also include an active cooling system 150 to provide sufficient airflow to keep the DUT 102 and/or test equipment 104 cool. In some embodiments, active cooling system 150 may comprise one or more fans and additional ventilation holes 164 in one or more panels 110 or 160.

As shown in FIG. 1, in some embodiments, the enclosure 100 may also include one or more divider panels 160. Divider panels 160 provide interior compartments or isolation zones within the enclosure 100, which can serve multiple purposes. For example, the divider panel 160 shown on the right side of FIG. 1 creates an interior compartment on the right side of enclosure 100 that allows handle 114, which in the illustrated embodiment is a large hole in the right side panel, to be used without risking that a user will come into contact with potentially high voltages present in the central compartment of the enclosure where DUT 102 is located. Likewise, the divider panel 160 shown on the left side of FIG. 1 creates an interior compartment on the left side of enclosure 100 that allows the handle on the left side panel to be used without risk to the user. Furthermore, the divider panel 160 on the left side of FIG. 1 is where the fans that are part of active cooling system 150 are mounted. Thus, the compartment created by this divider panel also forms an air plenum within the enclosure that improves the efficiency of active cooling system 150. A divider panel 160 may include ventilation holes 164 to help the active cooling system 150 keep the DUT 102 cool while it is being tested within the enclosure 100. As mentioned above, a divider panel 160 may engage with a slot defined by walls 1050 in an edge joint 130 to hold the divider panel in place. The divider panel 160 may be further supported and retained by one or more divider supports 162 that connect a panel 110 with the divider panel 160.

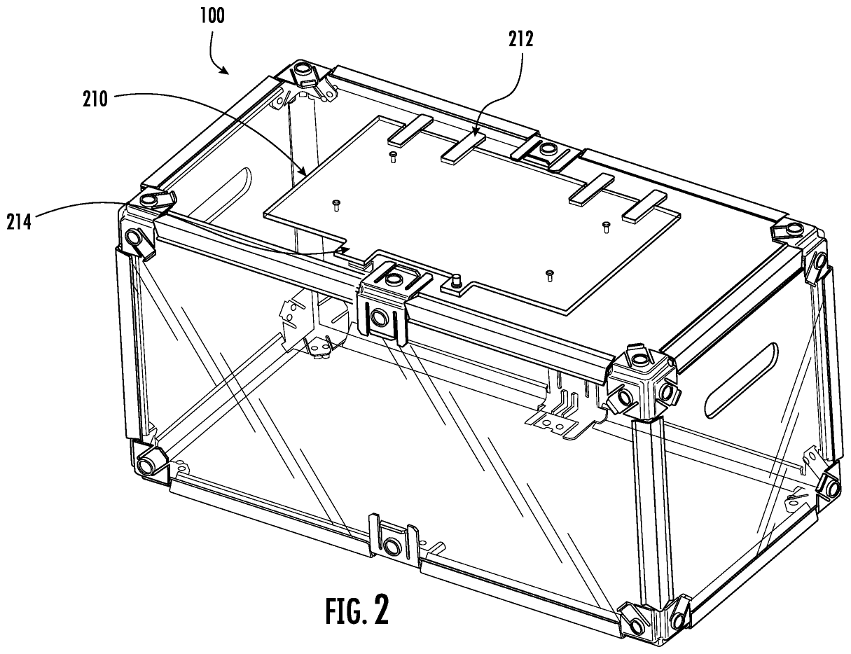

FIG. 2 illustrates additional features of a customizable safety enclosure 100, according to some embodiments of the disclosure. To set up the DUT 102 to be tested, in some embodiments, since the corner joints 120 and edge joints 130 are structured to be easily removeable by a user without tools, a user can access the inside the enclosure 100 by simply prying, i.e. “popping off,” the corner joints 120 and edge joints 130 necessary to remove the top panel 110. After DUT 102 and/or test equipment 104 setup is complete, the user can reinstall the top panel 110 by reattaching the associated corner joints 120 and edge joints 130, and proceed with testing. However, for even more convenient access to the inside of enclosure 100, in some embodiments, as shown in FIG. 2, the enclosure 100 includes an access door 210. Access door 210 may be attached to the enclosure 100, e.g. to a top panel 110, by one or more non-conductive elastomer hinges 212 which can be installed without using fasteners. Elastomer hinges 212 also prevent exposing a user to any high voltage inside the customizable safety enclosure 100 and uses a singular component that does not require additional fasteners. FIG. 2 illustrates a single-panel access door 210, but other embodiments may include more complex access doors 210, such as bi-fold or tri-fold doors.

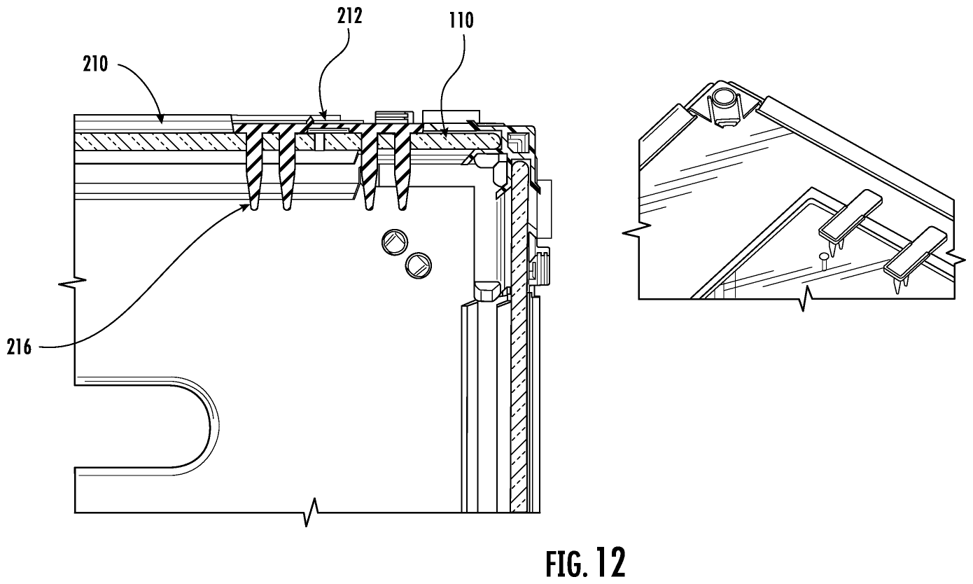

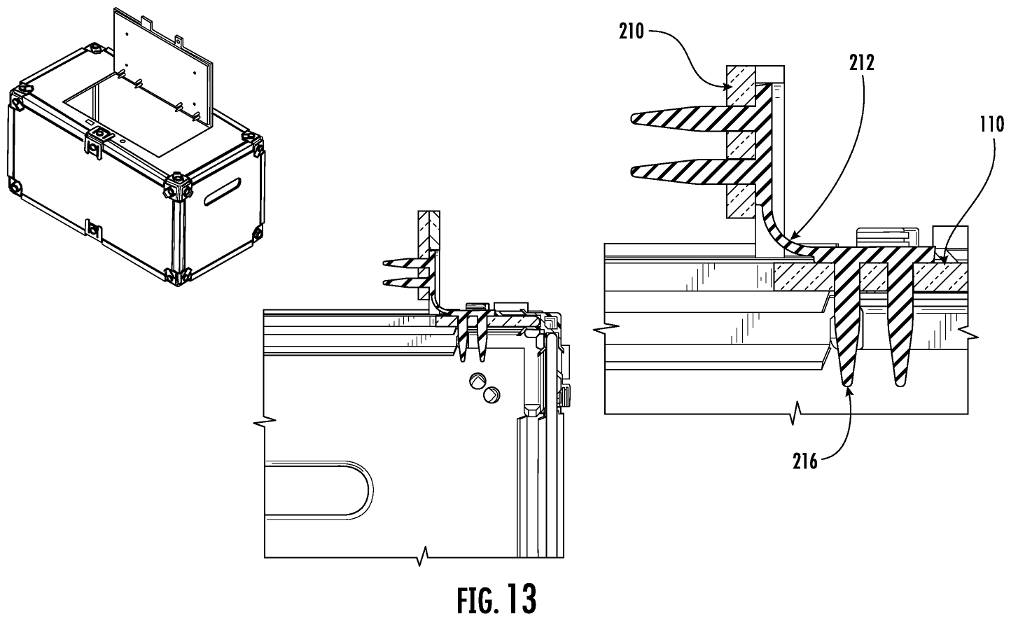

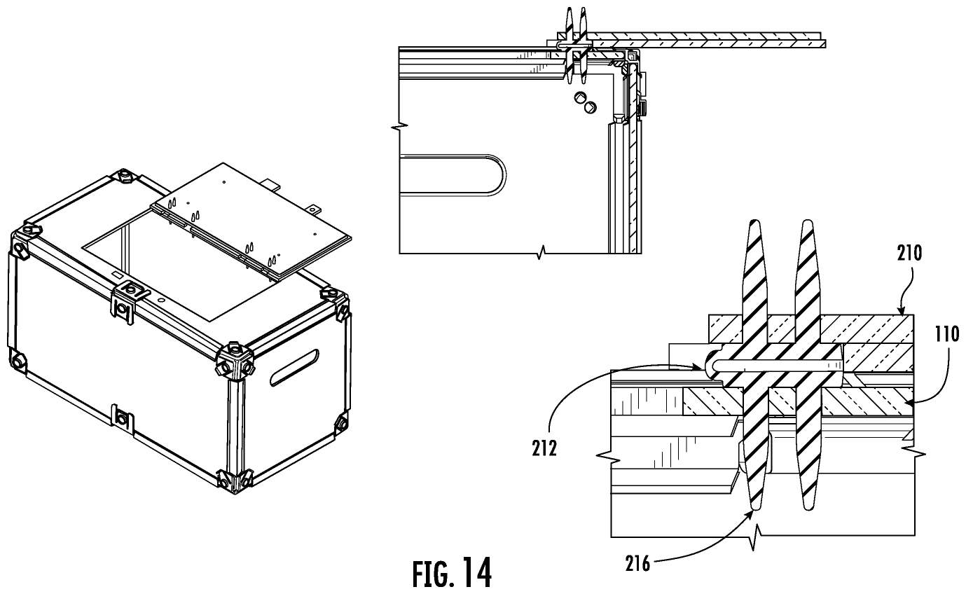

FIG. 12 illustrates the elastomer hinge 212 attached to a panel 110 of the enclosure 100 and a door assembly to form an access door 210 where the customer DUT resides. The range of motion can be from fully closed to fully open, and many positions in between, as illustrated by FIGS. 13 and 14. The hinge 212 includes long narrow and tapering cylinders 216 that are pulled through holes in the access door 210 and the mating panel 110. Once the main hinge portion is seated, additional pull narrows the cross-section of the cylinders 216 due to Poisson's Effect, allowing the passage of the cylinder's retaining material past the hole. Once released from the pull force, the free portion of the cylinder expands to the original size, creating a button diameter larger than the hole diameter, which then retains the hinge 212. The hinge 212 is an example of a stand-alone living hinge, making it unlikely to suffer from a cycle life limitation nor encounter mechanical failure. Thus, the hinge plays a key role within the customizable safety enclosure by providing simple installation, toolless installation, superior cycle life, and non-conductivity.

Returning to FIG. 2, in some embodiments, the enclosure 100 may also include a safety interlock circuit 214. The safety interlock circuit 214 is configured to de-energize the DUT circuits within the customizable safety enclosure 100. The safety interlock circuit 214 can cut off power with hazardous voltages and/or de-energize hazardous charge when the access door 210 is opened. In some embodiments, the safety interlock circuit may include a striker attached to the access door 210 and a switch or other detector to detect when the access door 210 is opened, and associated circuitry to cut off power to the DUT 102 and/or testing equipment 104 inside the enclosure. In some embodiments, the interlock circuit 214 may also include status lights and/or audible alarms to communicate to a user the hazard status of a DUT 102 and/or the open/closed status of the access door 210.

The custom nature of the safety enclosure design allows for customization of the panel meant to secure the DUT 102 with machined features that align to the mounting hole pattern of the DUT. This allows the opportunity to provide a solution that includes a non-conductive removeable DUT mounting post 170, as illustrated by FIG. 1, which secures to a panel 110 through a milled receiving pattern for each hole. Such post 170 is designed to provide a main method for securing a customer's DUT within the customizable safety enclosure and is removeable and installable, by a user, without using tools or fasteners, allowing quick and easy installation.

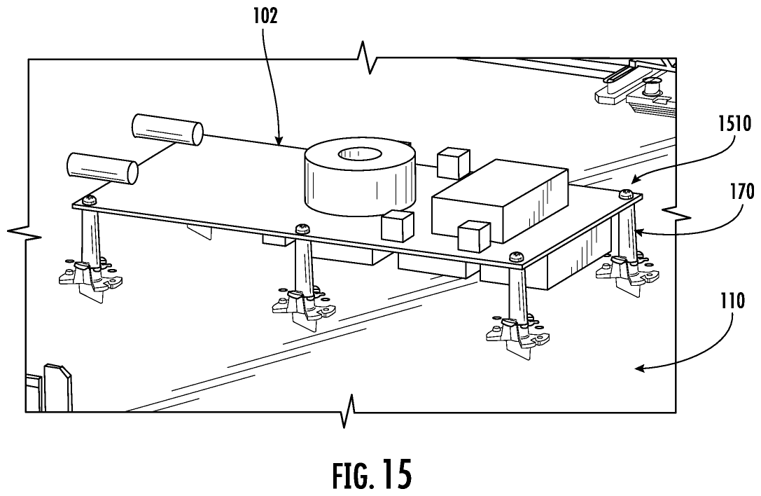

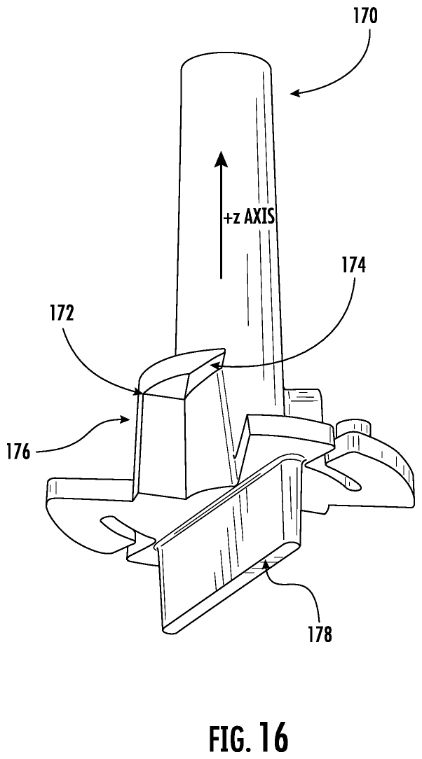

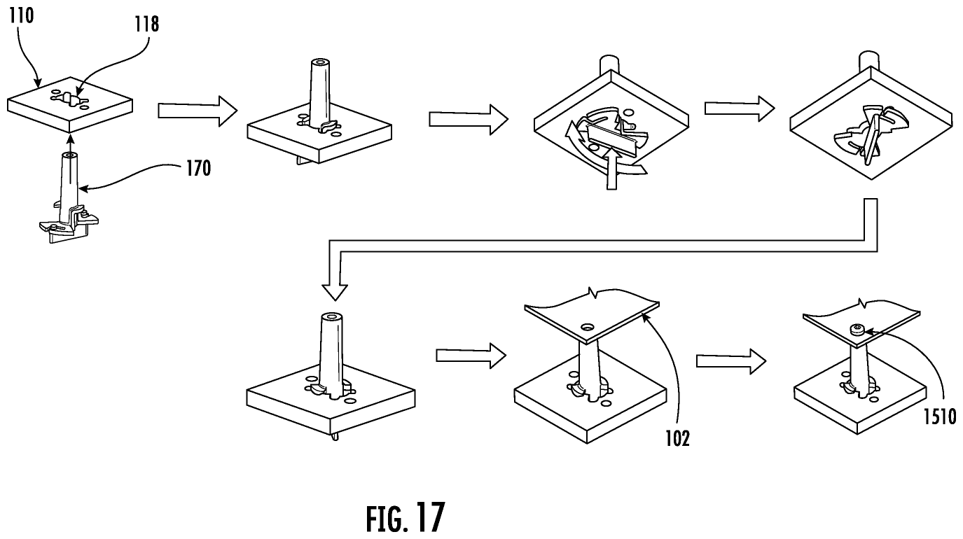

FIGS. 15-17 illustrate additional details of post 170, according to embodiments of the disclosure. As shown in FIG. 15, one or more posts 170 are installed through mounting holes formed in a panel 110. The DUT 102 is then secured to the posts 170 using, for example, mounting screws 1510. As shown in FIG. 16, a post 170 may include one or more flanges 172 that affix the post 170 in the z-axis direction when engaged with a mounting hole in a panel 110, a lead-in feature 174 on the flange 172 that helps the flange 172 climb over the edge of panel 110 as the post 170 is being installed, a wall 176 that sets the limit of rotation while post 170 is being installed, and a handle/grip 178 to allow a user to easily turn the post 170 during installation. FIG. 17 illustrates the process for installing the non-conductive mounting post 170. To assemble, the non-conductive mounting post 170 is inserted from below the clear plastic panel 110 through a mounting hole 118 until a bottom flange is seated to the bottom of the panel. The customer can then apply axial pressure while turning one-quarter of a revolution so a top flange can climb up onto a bearing surface of the panel until anti-rotation bosses of the post arrive and insert into holes of the panel receiving pattern The DUT 102 can be assembled to the panel by screwing through DUT printed circuit board (PCB) mounting holes into blind post holes using thread forming screws that generate the threads into the posts by displacing the material of the hole walls.

The non-conductive mounting post 170 limits a conductive path to the user, which allows thread-forming screw attachment of the DUT PCB by providing anti-rotate features that can endure the torque generated during the thread-forming process. Using thread forming screws to fasten the PCB allows a wide variation in thickness of PCB material, providing flexibility of PCB thickness. Thus, the non-conductive mounting post is capable of supporting larger panel thickness and wider range of DUT PCB thickness can be mounted. The use of these screws also provides an electrically insulative design because there is long creepage/clearance path between the exterior of the enclosure and the metal thread-forming and the associated DUT.

The design of this post 170 allows easy quarter-turn installation in the panel supporting the DUT since the panel will have already been prepared to match the hole pattern of the DUT PCB, providing users with ease in assembling the customizable safety enclosure. Additionally, this panel mount solution is toolless and saves time for users since users are not required to obtain a tool to insert the post into the panel. The design of the post also provides multiple fabrication options since the design is conductive to a lower resolution but physically robust 3D printed material and also contains features that allow the post to be easily used for a plastic injection molding process.

Post 170 works well in situations where a user needs to perform repeat testing of multiple DUTs that have the same form factor and mounting hole pattern, since the posts 170 are in fxed positions on a panel 110 that matches the monting hole pattern of the DUT 102. In situations where a user needs to test multiple different kinds of DUTs that have different mounting hole patterns, a user may choose to use a non-conductive printed circuit board (PCB) holder.

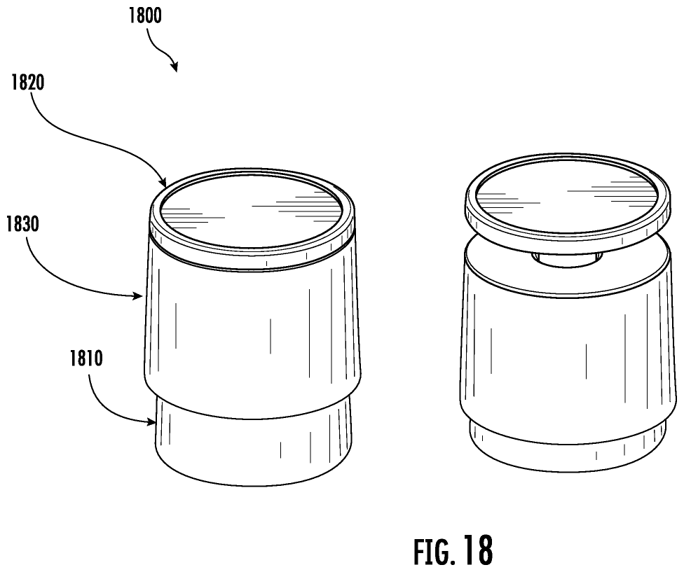

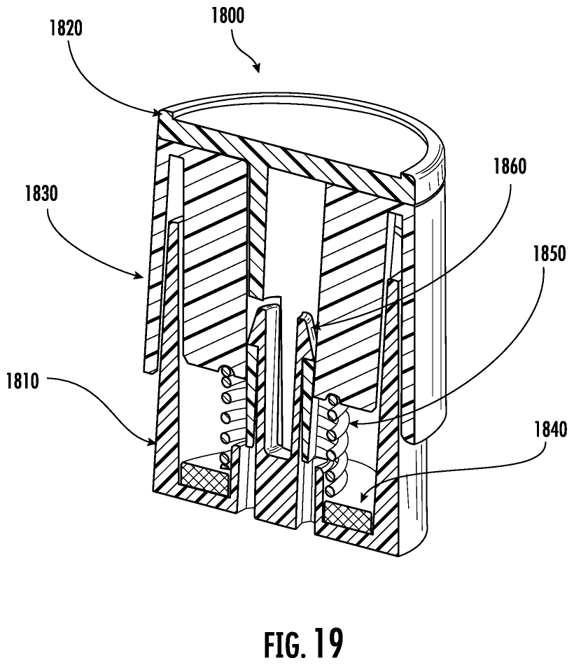

FIGS. 18-19 illustrate an example of a non-conductive PCB holder 1800, according to some embodiments of the disclsoure. FIG. 18 illustrates a non-conductive printed circuit board (PCB) holder 1800, that generally includes a base 1810, a clamp stem 1820, and a grip collar 1830. These components are non-conductive to greatly increase creepage distances which greatly reduces the hazard for certain voltage levels. As shown in FIG. 18, the grip collar 1830 is spring-loaded and moves between a closed position and an open position. The PCB holder 1800 is structured to hold a PCB DUT 102 between the grip collar 1830 and the clamp stem 1820. While normally in the closed position, a user would pull down the grip collar 1830 to the open position, allowing the user to insert the edge of a PCB between the inner surface of the clamp stem 1820 and the upper surface of the grip collar 1830. When released, an internal spring will clamp the PCB between those two surfaces.

FIG. 19 shows a cross-section through the center of the PCB holder 1800 and its internal elements. As shown in FIG. 19, the PCB holder 1800 includes a spring 1840, offering a slight pre-load on the grip collar 1830 against the clamp stem 1820 to keep it closed while not in use. A set of snaps 1860 connect the base 1810 to the clamp stem 1820. The side walls of the base 1810 help guide the grip collar 1830 when a user pulls it down to engage for clamping. A washer magnet 1840 sits at the bottom of the base 1810 so the opposing base surface can securely but removeably mount to a ferrous surface within the enclosure 100. That is, by adding a ferrous base plate to enclosure 100, one or more PCB holders 1800 can be located in any position on the ferrous base plate to match any mounting hole pattern on a DUT 102, and secured in position by the magnet 1840 in the base 1810. Thus, the PCB holder 1800 provides a highly flexible and re-configurable DUT mounting solution for enclosure 100.

By using non-conductive elements, the PCB holder 1800 allows the customizable safety enclosure 100 to be used and appropriate for hazardous voltage DUTS and environments due to the lack of conductive composition. Additionally, since the non-conductive PCB holder is not a conductive board edge holder with simply non-conductive coating, users do not have to worry about any current passing through the conductor to reach a user due to a scratch or abrasion on the coating. The overall geometry and topology of the PCB holder enables an insulative barrier between any portion of the DUT in contact with the holder that is at a hazardous voltage level and anyone contacting the holder.

Furthermore, in some embodiments, the enclosure 100 may also include task lighting to illuminate the DUT 102. Interior illumination could be provided with fiber-optics or battery-powered lighting, so as to not breach the enclosure with conductive power wires that might come into contact with hazardous voltages. And, in some embodiments, the enclosure may include cable routing retainers such as snaps, clips, and/or straps which can mount to panels to help route cables in a favorable path within the enclosure 100.

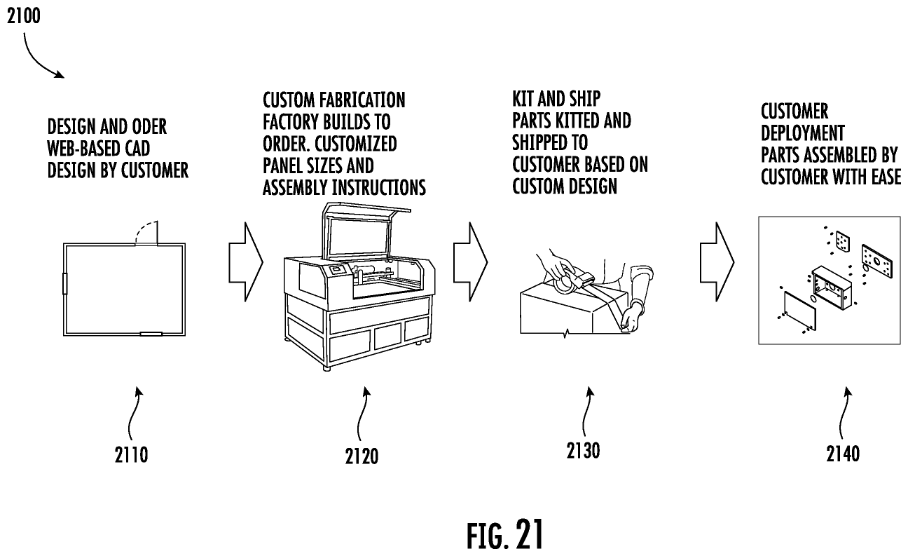

Embodiments of the disclosure also include systems and methods for supplying a customized safety enclosure, such as enclosure 100, to a customer. FIG. 21 is a diagram of an example method 2100 of supplying a customized safety enclosure for a DUT to a customer. The method 2100 provides quick turnaround between order placement and receipt of a kit for the customer's customizable safety enclosure. The method allows a quick and easy way of assembling and deploying a customer's customizable safety enclosure by avoiding the use of tools and many fasteners. The method relies on using simple slot insertions and snaps that are fast to assemble and allows users to quickly disassemble and flatten the customizable safety enclosure in its original packaging for efficient storage or transport. This method provides users an easy way of designing, configuring, assembling, and deploying their customizable safety enclosure.

The design and order phase 2110 illustrated by FIG. 21 may include using a contractor to host a web page dedicated to specifying and designing customer safety enclosures with input provided by the customer including information about their spatial environment, i.e. testing environment, and DUT size. Based on this information, the web page tool can create a rendering of what the customized safety enclosure would look like. The customer can then proceed to select various optional features of the customized safety enclosure. The web page tool can present 3D probehead models, or other testing equipment, within the enclosure rendering to ensure sizing takes into account their placement and proper mounting features are present. This system would allow real-time visualization of the CAD model which updates as the user makes changes and choose features. Real-time quoting could be included so users can understand the cost implications of different sizes and features by using a web-based interface.

During the custom fabrication phase 2120 illustrated by FIG. 21, each custom design will include a variety of fixed and variable components. Standard fixed components are present in all configurations and do not vary their design between configurations. They are the basic elements that provide structure and attachment points for the panels. These may include corner joints 120 and edge joints 130 illustrated in FIG. 1. Optional fixed components are parts that appear in some configurations where certain options are selected. These may include divider supports 162, PCB mounting posts 170 and/or PCB holder 1800, active cooling system 150, and their mounting fasteners. Both standard fixed component and the optional fixed components can be individually part numbered, ordered to forecast, and stocked in inventory. Variable components are custom fabricated to a particular customer's enclosure design size and support standard and optional features such as handles, ventilation, DUT mounting, and fan mounting. The panels 110 are scaled to the faces of the enclosure and support standard cable egress slots 112 and optional features. These parts would be fabricated on demand per an individual customer's specification from the design and order phase 2110. Hybrid components have both fixed and variable qualities, such as an edge guard 140. The edge guards 140 have a fixed cross-section but would need to be cut at varying lengths for different edges of the enclosure. The cuts would be fabricated on demand per an individual customer's specification from the design and order phase 2110. The custom fabrication phase 2120 also includes producing customized assembly instructions for the customer based on the components of their customized enclosure.

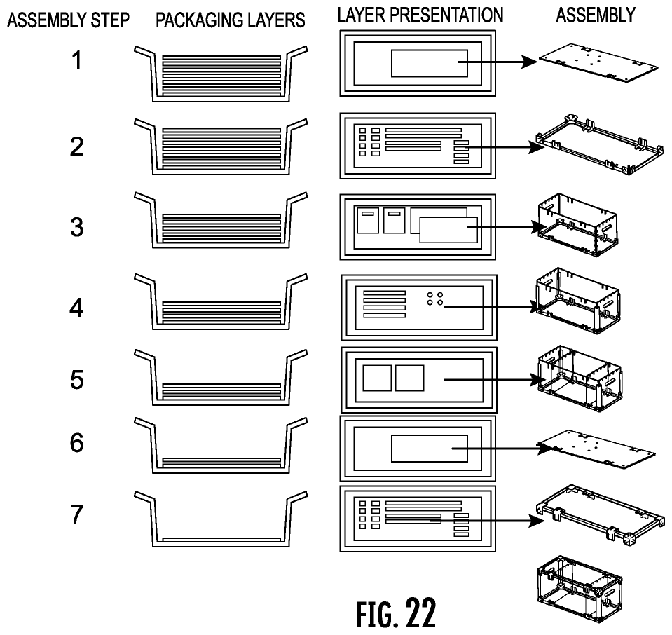

During the kit and ship phase 2130 illustrated by FIG. 21, parts are kitted for ease of assembly, with clear customized instructions, sequential positions that match assembly process, and clear labelling of parts to optimize the speed and instructional clarity of customer deployment. FIG. 22 illustrates how components of the customized safety enclosure may be packaged in layers substantially corresponding to the order of assembly. For example, the components needed for the first assembly step, i.e. typically the bottom-most components of the finished assembled enclosure, are presented on the top layer of the packaged components, while the components needed for the last assembly step, i.e. typically the top-most components of the finished assembly enclosure, are presented on the bottom layer of the packaged components. The packaged components and the customized assembly instructions are then sent to the customer for assembly.

During the customer deployment phase 2140 illustrated by FIG. 21, unpacking with components are presented in assembly order. Starting with instructions, the parts are presented to the customer in an order that mirrors the assembly order. So as parts and packaging are removed, the next part may be revealed or an arrow pointing to the next part is shown. This approach can be expanded with packaging trays that present sets of related parts but are stacked in the assembly order. Assembly instructions may be printed on the packaging layers themselves to ensure fast assembly but eliminating repeated assembly instruction manual lookups. Clear visual instructions can also be offered that are customized to the customer's configuration. The instructions would illustrate and describe the exact design configuration shipped to the customer. For example, if a fan option is selected, the instructions will provide text instructions on how to install the fan and a computer-generated illustration of the fan being assembled in the exact location specified by the custom design. Easily assembled components utilize snaps and slots. Minimal to no tools and individual fasteners would be required to save on assembly time.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.
Example 1 is a customizable safety enclosure for a device under test (DUT), the enclosure comprising: a plurality of non-conductive panels to enclose the DUT; and a plurality of non-conductive removeable corner joints each configured to secure a corner of the enclosure.
Example 2 is the enclosure of claim 1, further comprising a cable egress opening.
Example 3 is the enclosure of either example 1 or 2, in which the corner joints are removeable and installable, by a user, without using tools or fasteners.
Example 4 is the enclosure of any of examples 1 to 3, in which the corner joints are structured to be installable symmetrically in three possible orientations.
Example 5 is the enclosure of any of examples 1 to 4, further comprising a non-conductive removable edge joint configured to secure an edge of the enclosure.
Example 6 is the enclosure of example 5, in which the edge joint is removeable and installable, by a user, without using tools or fasteners.
Example 7 is the enclosure of example 5, in which the edge joint can be used in a symmetrically in two possible orientations.
Example 8 is the enclosure of any of examples 1 to 7, further comprising an edge guard.
Example 9 is the enclosure of any of examples 1 to 8, further comprising an active cooling system.
Example 10 is the enclosure of any of examples 1 to 9, further comprising a divider panel.
Example 11 is the enclosure of example 10, in which the divider panel forms an air plenum within the enclosure.
Example 12 is the enclosure of any of examples 1 to 11, further comprising an access door.
Example 13 is the enclosure of example 12, in which the access door is attached by a non-conductive elastomer hinge.
Example 14 is the enclosure of example 12, further comprising a safety interlock circuit.
Example 15 is the enclosure of any of examples 1 to 14, further comprising a non-conductive removeable post to support the DUT within the enclosure.
Example 16 is the enclosure of example 15, in which the post is removeable and installable, by a user, without using tools or fasteners.
Example 17 is the enclosure of any of examples 1 to 16, further comprising a non-conductive printed circuit board (PCB) holder.
Example 18 is the enclosure of example 17, in which the PCB holder includes a clamp stem, a grip collar, a base, and a spring structured to put a force on the grip collar to hold the DUT between the grip collar and the clamp stem.
Example 19 is the enclosure of example 17, further comprising a ferrous base plate, in which the PCB holder includes a magnet.
Example 20 is the enclosure of any of examples 1 to 19, further comprising one or more of fiber-optic task lighting, battery-powered task lighting, and cable routing retainers.
Example 21 is a method of supplying a customized safety enclosure for a device under test (DUT) to a customer, the method comprising: receiving information from the customer about the DUT size and testing environment, fabricating one or more variable components of the enclosure, producing custom assembly instructions for the enclosure, packaging a plurality of components of the enclosure including the variable components and one or more fixed components, and sending the package of components and the custom assembly instructions to the customer.
Example 22 is the method of example 21, in which receiving information from the customer about the DUT size and testing environment comprises receiving the information through a web-based interface.
Example 23 is the method of example 21 or 22, in which receiving information from the customer about the DUT size and testing environment comprises accepting a CAD model file of the DUT from the customer.
Example 24 is the method of example 23, in which receiving information from the customer about the DUT size and testing environment comprises using the CAD model to design the customized enclosure.
Example 25 is the method of any of examples 21 to 24, further comprising generating a 3D real-time CAD design of the customized safety enclosure.
Example 26 is the method of any of examples 21 to 25, in which producing custom assembly instructions for the enclosure comprises producing visual instructions describing the exact configuration of the customized safety enclosure to be shipped to the customer.
Example 27 is the method of any of examples 21 to 26, in which in which receiving information from the customer about the DUT size and testing environment comprises receiving a selection from the customer of panel sizes in one of flat, small, and tall form factor variations.
Example 28 is the method of any of examples 21 to 27, in which packaging the plurality of components of the enclosure comprises packaging the components so they are presented to the customer in sequential positions that match the assembly process.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

I/We claim:

1. A customizable safety enclosure for a device under test (DUT), the enclosure comprising:
a plurality of non-conductive panels to enclose the DUT; and
a plurality of non-conductive removeable corner joints each configured to secure a corner of the enclosure.

2. The enclosure of claim 1, further comprising a cable egress opening.

3. The enclosure of claim 1, in which the corner joints are removeable and installable, by a user, without using tools or fasteners.

4. The enclosure of claim 1, in which the corner joints are structured to be installable symmetrically in three possible orientations.

5. The enclosure of claim 1, further comprising a non-conductive removable edge joint configured to secure an edge of the enclosure.

6. The enclosure of claim 5, in which the edge joint is removeable and installable, by a user, without using tools or fasteners.

7. The enclosure of claim 5, in which the edge joint can be used in a symmetrically in two possible orientations.

8. The enclosure of claim 1, further comprising an edge guard.

9. The enclosure of claim 1, further comprising an active cooling system.

10. The enclosure of claim 1, further comprising a divider panel.

11. The enclosure of claim 10, in which the divider panel forms an air plenum within the enclosure.

12. The enclosure of claim 1, further comprising an access door.

13. The enclosure of claim 12, in which the access door is attached by a non-conductive elastomer hinge.

14. The enclosure of claim 12, further comprising a safety interlock circuit.

15. The enclosure of claim 1, further comprising a non-conductive removeable post to support the DUT within the enclosure.

16. The enclosure of claim 15, in which the post is removeable and installable, by a user, without using tools or fasteners.

17. The enclosure of claim 1, further comprising a non-conductive printed circuit board (PCB) holder.

18. The enclosure of claim 17, in which the PCB holder includes a clamp stem, a grip collar, a base, and a spring structured to put a force on the grip collar to hold the DUT between the grip collar and the clamp stem.

19. The enclosure of claim 17, further comprising a ferrous base plate, in which the PCB holder includes a magnet.

20. The enclosure of claim 1, further comprising one or more of fiber-optic task lighting, battery-powered task lighting, and cable routing retainers.
